(19) United States
(12) Patent Application Publication
(10) Pub. No.: US 2018/0037019 A1
(43) Pub. Date: Feb. 8, 2018

(54) CONTROLLED GRAIN SIZE STRUCTURES

(71) Applicant: Hamilton Sundstrand Corporation, Charlotte, NC (US)

(72) Inventors: John A. Sharon, West Hartford, CT (US); Amra Peles, South Windsor, CT (US); Rhonda R. Willigan, Manchester, CT (US); Tahany I. El-Wardany, Bloomfield, CT (US); Mark R. Jaworowski, Glastonbury, CT (US)

(21) Appl. No.: 15/230,754

(22) Filed: Aug. 8, 2016

(51) Int. Cl. B32B 37/24; C23C 18/16; C25D 5/02; B32B 7/08; C23C 14/04; B32B 37/10; B32B 3/26; C23C 14/22; C25D 5/10

(52) U.S. Cl. CPC B32B 37/24; C23C 14/22; C23C 18/1605; C23C 18/1651; C25D 5/022; C25D 5/10; C23C 14/042; B32B 37/10; B32B 3/266; B32B 7/08; B32B 2037/243; B32B 2037/246; B32B 2255/28; B32B 2307/542; B32B 2307/552; B32B 2255/205

(57) ABSTRACT

A structure includes a first substrate and a variable grain layer disposed on or formed into the first substrate. The variable grain layer includes a first grain portion having a first grain size and second grain portion having a second grain size. The first grain size is smaller than the second grain size.

### BACKGROUND

### 1. Field

The present disclosure relates to structures, more specifically to controlled grain size structures.

### 2. Description of Related Art

Metals with grain sizes below 1 micron, for example, are known to have strength, hardness, and fatigue endurance limits superior to coarser grain (i.e., greater than 1 micron) metals. These property enhancements stem from the Hall-Petch grain size strengthening effect whereby smaller grains results in higher strength. Challenges exist in synthesizing useful components that extract benefit from submicron grain metal.

Such conventional methods and systems have generally been considered satisfactory for their intended purpose. However, there is still a need in the art for improved structures and methods for making such structures. The present disclosure provides a solution for this need.

### SUMMARY

A structure includes a first substrate and a variable grain layer disposed on or formed into the first substrate. The variable grain layer includes a first grain portion having a first grain size and second grain portion having a second grain size. The first grain size is smaller than the second grain size.

The first grain size can be submicron. In certain embodiments, the second grain size can be 1 micron or greater. The substrate can include a sheet shape and/or any other suitable shape. The variable grain layer can be made of and/or can include metal, for example.

In certain embodiments, the variable grain layer can include a thickness greater than or equal to the substrate, or any other suitable thickness. A second substrate can be disposed on the variable grain layer opposite the first substrate to form a sandwich structure.

An aperture can be defined through the first substrate, the variable grain layer, and the second substrate at the first grain portion. The aperture can be configured to receive a fastener, for example.

The second substrate can be compression bonded (e.g., roll bonded) to the variable grain layer or bonded in any other suitable manner. The first grain portion and the second grain portion can be defined in strips.

In accordance with at least one aspect of this disclosure, a method for forming a structure having variable grain sizes includes creating a first grain portion having a first grain size on a first substrate and creating a second grain portion having a second grain size on the first substrate. The first grain size is smaller than the second grain size and the first grain portion and the second grain portion form at least part of a variable grain layer.

Creating a first grain portion can include masking a portion of the first substrate and allowing the first grain portion to deposit on the substrate where there is no masking. Creating the second grain portion can include masking the first grain portion and allowing a second grain portion to deposit on the substrate where there is no masking. Creating the first and/or second grain layer can include at least one of vapor deposition, electroplating, chemical plating, mechanical working of the surface of the substrate, or disposing a preformed variable grain layer.

The method can include disposing a second substrate on the variable grain layer to form a sandwich structure. The method can include bonding the second substrate to the variable grain layer.

Bonding can include roll bonding the sandwich structure in a roller system. The method can include controlling grain size as a function of one or more rolling parameters of the roller system. The one or more rolling parameters can include at least one of heating, cooling, compression, or speed.

These and other features of the systems and methods of the subject disclosure will become more readily apparent to those skilled in the art from the following detailed description taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1 is a perspective view of an embodiment of a structure in accordance with this disclosure, shown having a variable grain layer disposed on a substrate;

FIG. 2 is a perspective, partially sectional view of FIG. 1, shown having a second substrate disposed on the variable grain layer to form a sandwich structure, and an aperture defined through the sandwich structure at a first grain portion of the variable grain layer.

FIG. 3 is a cross-sectional view of the embodiment of FIG. 2; and

FIG. 4 is a schematic flow view of an embodiment of a method in accordance with this disclosure.

### DETAILED DESCRIPTION

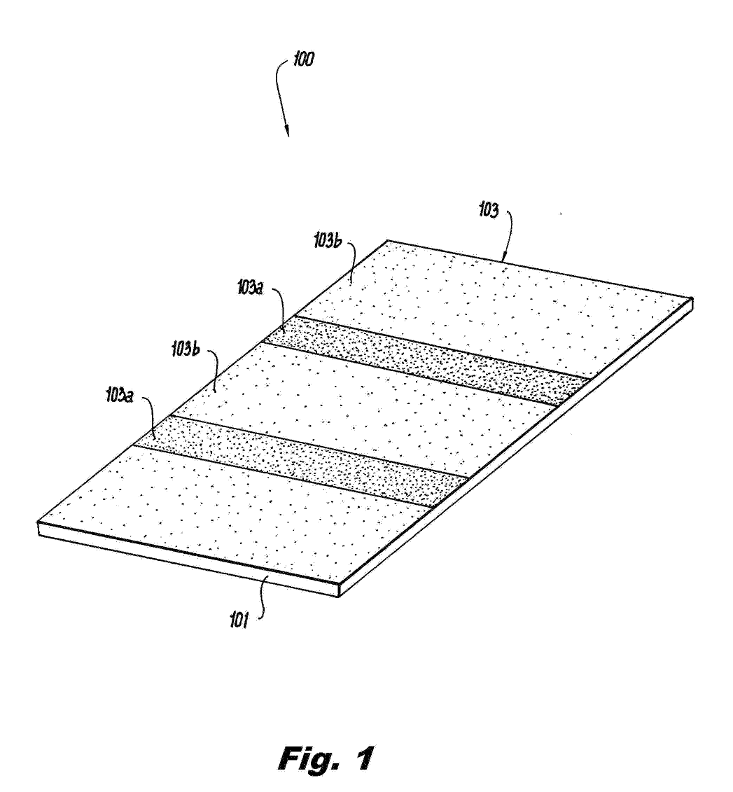

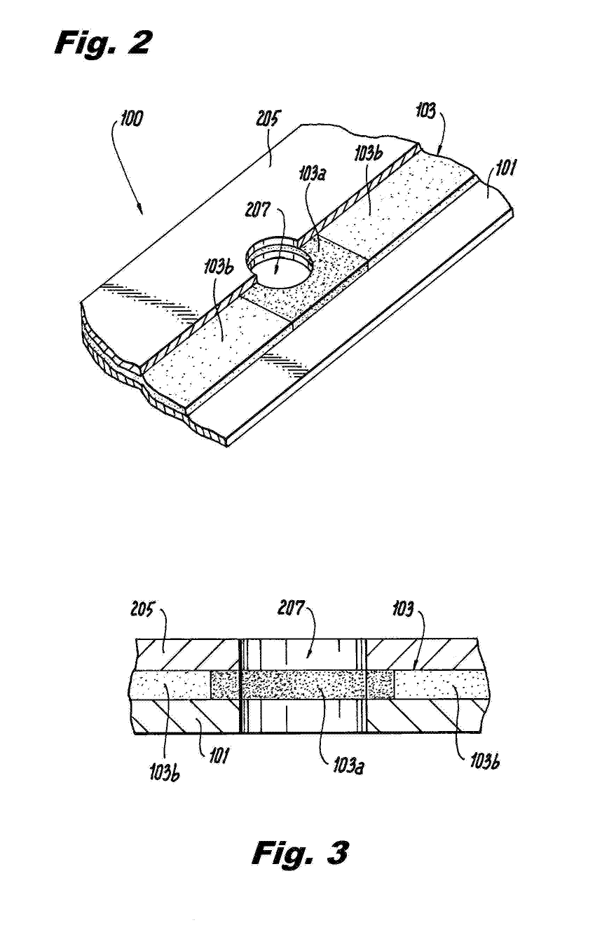

Reference will now be made to the drawings wherein like reference numerals identify similar structural features or aspects of the subject disclosure. For purposes of explanation and illustration, and not limitation, an illustrative view of an embodiment of a structure in accordance with the disclosure is shown in FIG. 1 and is designated generally by reference character 100. Other embodiments and/or aspects of this disclosure are shown in FIGS. 2-4. The systems and methods described herein can be used to provide structures having beneficial material properties.

Referring to FIG. 1, a structure 100 includes a first substrate 101 and a variable grain layer 103 disposed on or formed into the first substrate 101. The substrate 101 can include a sheet shape and/or any other suitable shape. The substrate can include a metal (e.g., stainless steel) and can have any suitable grain size (e.g., coarse such as greater than 1 micron).

The variable grain layer 103 can include one or more first grain portions 103a having a first grain size and one or more second grain portions 103b having a second grain size. The first grain size is smaller than the second grain size. The variable grain layer 103 can include a metal material, for example. Any other suitable material is contemplated herein.

In certain embodiments, the variable grain layer 103 can be deposited on the substrate 101. In certain embodiments, the variable grain layer 103 is formed from the first substrate 101 and/or forms a separate layer.

In certain embodiments, the first grain size can be submicron. In certain embodiments, the second grain size can be 1 micron or greater.

In certain embodiments, the variable grain layer 103 can include a thickness greater than or equal to the substrate 101. However, any other suitable thickness (e.g., less than the substrate 101) is contemplated herein.

Referring to FIGS. 2 and 3, a second substrate 205 can be disposed on the variable grain layer 103 opposite the first substrate 101 to form a sandwich structure as shown. In certain embodiments, the second substrate 205 can be the same material and/or dimensions (e.g., shape and/or size) as the first substrate 101. Any other suitable dimensions and/or material is contemplated herein.

As shown in FIGS. 2 and 3, an aperture 207 can be defined through the first substrate 101, the variable grain layer 103, and the second substrate 205 at the first grain portion 103a. The aperture 207 can be configured to receive a fastener (e.g., a bolt), for example.

The first and/or second substrate 101, 205 can be compression bonded (e.g., roll bonded) to the variable grain layer 103, and/or bonded in any other suitable manner. As shown in FIGS. 1-3, the first grain portion 103a and the second grain portion 103b can be defined in strips. Any other suitable shape for the first and second grain portions 103a, 103b is contemplated herein.

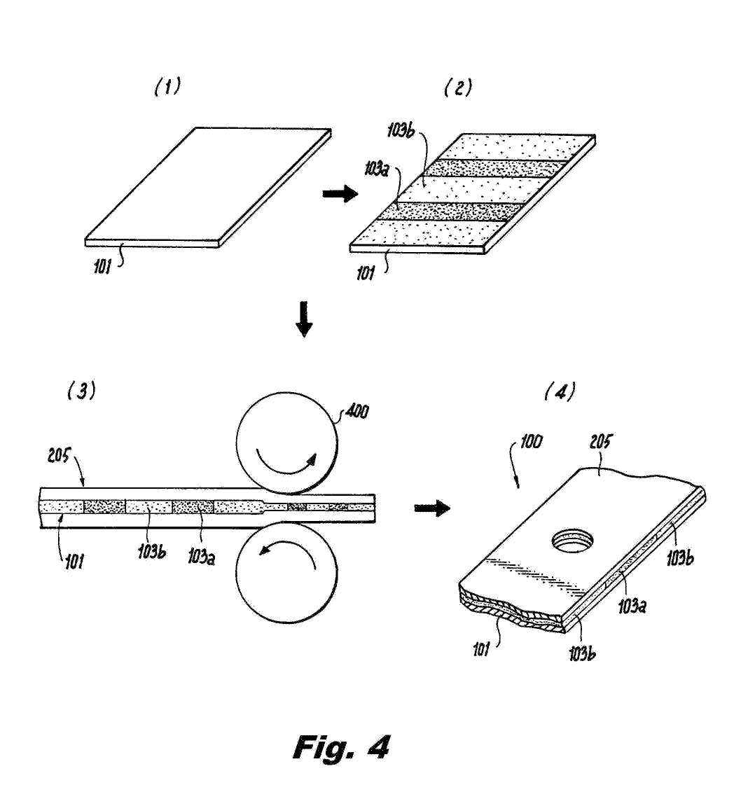

Referring additionally to FIG. 4, in accordance with at least one aspect of this disclosure, a method for forming a structure 100 having variable grain sizes includes creating a first grain portion 103a having a first grain size on a first substrate 101 and creating a second grain portion 103b having a second grain size on the first substrate 101. As described above, the first grain size can be smaller than the second grain size and the first grain portion and the second grain portion can form at least part of a variable grain layer 103. Creating the first and/or second grain layer 103a, 103b can include at least one of vapor deposition, electroplating (e.g., electro-chemical plating), chemical plating, mechanical working of the surface of the substrate, or disposing a preformed variable grain layer 103 on the first substrate 103.

Creating a first grain portion 103a can include masking a portion of the first substrate 101 and allowing the first grain portion 103a to deposit on the substrate 101 where there is no masking. Similarly, creating the second grain portion 103b can include masking the first grain portion 103a and allowing a second grain portion 103a to deposit on the substrate 101 where there is no masking.

The method can include disposing a second substrate 207 on the variable grain layer to form a sandwich structure. The method can include bonding the second substrate 205 to the variable grain layer 103.

Bonding can include roll bonding the sandwich structure in a roller system 400 as shown in FIG. 4. Any other suitable bonding means is contemplated herein.

The method can include controlling grain size as a function of one or more rolling parameters of the roller system 400. The one or more rolling parameters can include at least one of temperature (heating and/or cooling), compression load, thickness reduction level, or speed, for example. The structure 100 can be machined for any suitable use after bonding, for example. As described above, in certain embodiments, a graded grain structure can be achieved with a hybrid manufacturing approach that combines bottom up synthesis of small grain metal on a substrate formed into a sandwich panel with roll bonding.

Embodiments as described above can harness strong submicron grain metal, for example, to create components with improved mechanical performance. The strong submicron grain metal can be strategically incorporated into regions of the structure where high stress develops during use of the structure, for example. Embodiments of this disclosure enable components to achieve improvements in fatigue resistance, strength, lifetime, and more that are afforded by submicron metal.

The methods and systems of the present disclosure, as described above and shown in the drawings, provide for structures with superior properties. While the apparatus and methods of the subject disclosure have been shown and described with reference to embodiments, those skilled in the art will readily appreciate that changes and/or modifications may be made thereto without departing from the spirit and scope of the subject disclosure.

What is claimed is:

1. A structure, comprising:
a first substrate; and
a variable grain layer disposed on or formed into the first substrate, wherein the variable grain layer includes a first grain portion having a first grain size and second grain portion having a second grain size, wherein the first grain size is smaller than the second grain size.

2. The structure of claim 1, wherein the first grain size is submicron.

3. The structure of claim 2, wherein the second grain size is about 1 micron or greater.

4. The structure of claim 1, wherein the first substrate includes a sheet shape.

5. The structure of claim 4, wherein the variable grain layer includes a thickness greater than or equal to the first substrate.

6. The structure of claim 1, further comprising a second substrate disposed on a side of the variable grain layer opposite the first substrate to form a sandwich structure.

7. The structure of claim 6, further comprising an aperture defined through the first substrate, the variable grain layer, and the second substrate in the first grain portion.

8. The structure of claim 7, wherein the aperture is configured to receive a fastener.

9. The structure of claim 6, wherein the second substrate is compression bonded to the variable grain layer.

10. The structure of claim 6, wherein the first grain portion and the second grain portion are defined in strips.

11. The structure of claim 1, wherein the variable grain layer is made of or includes metal.

12. A method for forming a structure having variable grain sizes, comprising:
creating a first grain portion having a first grain size on a first substrate; and
creating a second grain portion having a second grain size on the first substrate, wherein the first grain size is smaller than the second grain size, wherein the first grain portion and the second grain portion form at least part of a variable grain layer.

13. The method of claim 12, wherein the creating a first grain portion includes masking a portion of the first substrate and depositing the first grain portion on the substrate where there is no masking.

14. The method of claim 13, wherein the creating the second grain portion includes masking the first grain portion and depositing the second grain portion on the substrate where there is no masking.

15. The method of claim 12, further comprising disposing a second substrate on the variable grain layer to form a sandwich structure.

16. The method of claim 15, further comprising bonding the second substrate to the variable grain layer.

17. The method of claim 16, wherein the bonding includes roll bonding the sandwich structure in a roller system.

18. The method of claim 17, further comprising controlling grain size as a function of one or more rolling parameters of the roller system.

19. The method of claim 18, wherein the one or more rolling parameters include at least one of heating, cooling, compression, or speed.

20. The method of claim 12, wherein creating the first and/or second grain layer includes at least one of vapor deposition, electroplating, chemical plating, mechanical working of the surface of the substrate, or disposing a preformed variable grain layer.
